(19) United States
(12) Patent Application Publication
(10) Pub. No.: US 2006/0043588 A1
(43) Pub. Date: Mar. 2, 2006

(54) Semiconductor device including a low-k metallization layer stack for enhanced resistance against electromigration

(76) Inventors: Christof Streck, Coswig (DE); Hartmut Ruelke, Dresden (DE); Michael Kiene, Radebeul (DE)

Correspondence Address: WILLIAMS, MORGAN & AMERSON, 10333 RICHMOND, SUITE 1100, HOUSTON, TX, 77042, US

(21) Appl. No.: 11/114,335

(22) Filed: Apr. 26, 2005

(30) Foreign Application Priority Data
Aug. 31, 2004 (DE) 10 2004 042 168.4

(51) Int. Cl. H01L 23/48

(52) U.S. Cl. 257/751

(57) ABSTRACT

A technique is disclosed which enables the formation of a metallization layer being substantially comprised of a low-k dielectric material, wherein a compressive stress layer provides enhanced electromigration behavior of the metallization layer. In particular embodiments, a compressive silicon dioxide layer may be formed on or in the vicinity of a dielectric barrier layer and a metallization layer based on SiCOH.

### BACKGROUND OF THE INVENTION

1. Field of the Invention

Generally, the present invention relates to the fabrication of integrated circuits, and, more particularly, to the formation of metallization layers of reduced permittivity.

2. Description of the Related Art

Semiconductor devices are typically formed on substantially disc-shaped substrates made of any appropriate material. The majority of semiconductor devices, including highly complex electronic circuits, currently, and in the foreseeable future, will be manufactured on the basis of silicon, thereby rendering silicon substrates and silicon-containing substrates, such as silicon-on-insulator (SOI) substrates, viable carriers for forming semiconductor devices, such as microprocessors, SRAMs, ASICs (application specific ICs) and the like. The individual integrated circuits are arranged in an array form, wherein most of the manufacturing steps, which may involve up to 500 and more individual process steps in sophisticated integrated circuits, are performed simultaneously for all chip areas on the substrate, except for photolithography processes, metrology processes and packaging of the individual devices after dicing the substrate. Thus, economical constraints drive semiconductor manufacturers to steadily increase the substrate dimensions, thereby also increasing the area available for producing actual semiconductor devices and thus increasing production yield, and also reduce device dimensions in view of performance criteria, as typically lower transistor dimensions provide increased operating speeds.

In modern integrated circuits, the circuit elements are formed in and on a semiconductor layer, while most of the electrical connections are established in one or more “wiring” layers, also referred to as metallization layers, wherein the electrical characteristics, such as resistivity, electromigration, etc., of the metallization layers significantly affect the overall performance of the integrated circuit. Electromigration is a phenomenon of temperature and/or electric field induced material transport in a metal line, which is observable at higher current densities in a metal line, thereby resulting in device degradation or even device failure.

Due to the ongoing demand for shrinking the feature sizes of highly sophisticated semiconductor devices, copper in combination with a low-k dielectric material has become a frequently used alternative in the formation of so-called interconnect structures comprising metallization layers having metal line layers and intermediate via layers. Metal lines act as intralayer connections and vias act as interlayer connections, which commonly connect individual circuit elements to provide the required functionality of the integrated circuit. Typically, a plurality of metal line layers and via layers stacked on top of each other are necessary to realize the connections between all internal circuit elements and I/O (input/output), power and ground pads of the circuit design under consideration. Hereby, the metal lines provide the electrical connections within a single metallization layer, whereas the vias are formed through the interlayer dielectric material to connect two metal lines of vertically adjacent metallization layers.

For extremely scaled integrated circuits, the signal propagation delay is no longer limited by the field effect transistors but is limited, owing to the increased density of circuit elements, which requires an even more increased number of electrical connections, by the close proximity of the metal lines, since the line-to-line capacitance is increased. This fact, in combination with a reduced conductivity of the lines due to a reduced cross-sectional area, results in increased RC time constants. For this reason, traditional dielectrics such as silicon dioxide (k>3.6) and silicon nitride (k>5) are increasingly replaced in metallization layers by dielectric materials having a lower permittivity, which are therefore also referred to as low-k dielectrics having a relative permittivity of approximately 3 or less. However, the density and mechanical stability or strength of the low-k materials may be significantly less compared to the well-approved dielectrics silicon dioxide and silicon nitride. As a consequence, the electrical behavior of the metallization layers, although being superior in view of device performance, may deteriorate with respect to reliability compared to devices having a conventional metallization layer. Therefore, a hybrid technique is frequently employed where the dielectric material for the via layers is comprised of silicon dioxide while the metal line layers are formed of a low-k material, thereby sacrificing some of the advantages in view of operating speed offered by the low-k material for the benefit of an enhanced reliability, for instance with respect to electromigration, compared to a metallization layer fully fabricated from a low-k material.

With reference to FIG. 1, a typical conventional semiconductor device is described, which includes a metallization layer on the basis of a low-k material. In FIG. 1, a semiconductor device 100 comprises a substrate 101 that may include any circuit elements, such as transistor elements, capacitors and the like. For convenience, these circuit elements are not shown. Formed on the substrate 101, which may represent a bulk silicon substrate or an SOI substrate, is a dielectric layer 102, which may be comprised, at least partially, of a low-k material such as hydrogen-containing silicon oxycarbide (SiCOH) or any other suitable materials, including polymer materials and the like. A metal region 103 is formed within the dielectric layer 102, wherein the metal region 103 is provided to represent any highly conductive portion, such as a contact portion or a metal line of a metallization layer. The metal region 103 may be separated from the material of the dielectric layer 102 by a barrier layer 104, which is typically provided as a layer for reducing the diffusivity of metal atoms into the dielectric layer 102 and to also reduce the diffusion of atoms from the dielectric layer 102 into the metal region 103. Moreover, the barrier layer 104 may also enhance the adhesion of the metal with respect to the dielectric material. In sophisticated devices, the metal region 103 may comprise copper and the barrier layer 104 may be comprised of one or more layers including tantalum, tantalum nitride, titanium, titanium nitride and the like. Formed above the dielectric layer 102 and the metal region 103 is a dielectric barrier layer or capping layer 105 comprised of a dielectric material that substantially prevents diffusion of metal atoms of the metal region 103 into overlying regions. In particular, the metal region 103 may comprise copper which readily diffuses in a plurality of dielectric materials, such as silicon dioxide. Hence, the dielectric barrier layer 105 may comprise silicon nitride or nitrogen-enriched silicon carbide, which exhibits a high diffusion blocking effect and may also act as an etch stop layer during subsequent etch processes.

A metallization layer 113 is formed on the dielectric barrier layer 105, wherein the metallization layer 113 includes a via layer 111 and a metal line layer 112. The metal line layer 112 comprises a dielectric layer 110, which is typically comprised of a low-k material such as SiCOH. Moreover, a metal-filled trench 107, which may contain a copper-based metal, is formed within the dielectric layer 110. Similarly, the via layer 111 comprises a dielectric layer 109 and a metal-filled via 106. The metal-filled trench 107 and via 106 are separated from the respective dielectric materials by a conductive barrier layer 108, which may have the same composition as the barrier layer 104. A dielectric barrier layer or a capping layer 114 is formed on the dielectric layer 110 and the metal-filled trench 107. Regarding the material composition of the barrier layer 114, the same criteria apply as discussed with reference to the barrier layer 105.

In view of increased performance, it is desirable to keep the permittivity of the metallization layer 113 as low as possible to minimize the parasitic capacitances and thus the signal propagation delay. It turns out, however, that forming both the dielectric layer 109 and the dielectric layer 110 of a low-k material, although lowering the overall permittivity of the metallization layer 113, may result in poor reliability of the semiconductor device 100 caused by increased electromigration effects in the metal region 103 and the metal-filled trench 107 and via 106. It is believed that electromigration is significantly affected by the condition of any interfaces of the metal with the surrounding dielectric material, such as, for instance, interfaces 103a and 107a, so that, especially along such interfaces, electrical field and/or temperature induced material transport occurs. The condition of the interfaces, such as the interfaces 103a and 107a, is, among other things, determined by the mechanical characteristics of the surrounding dielectric material and, hence, the electromigration behavior of conventional dielectrics, such as silicon dioxide, is superior compared to the behavior of low-k materials, as usually the low-k materials exhibit a reduced mechanical strength. For this reason, frequently the dielectric layer 109, i.e., the dielectric of the via layer 111, is provided in the form of a material having enhanced mechanical strength compared to a low-k material and thus silicon dioxide, typically doped with fluorine, may be used as the dielectric material. In this way, an improved behavior with respect to electromigration is balanced against minimizing the total permittivity of the metallization layer 113.

A typical process flow for forming the semiconductor device 100 may comprise the following processes. After completing any circuit elements, the dielectric layer 102 and the metal region 103 with the conductive barrier layer 104 may be formed by a well-established process sequence. It may be assumed, for instance, that the dielectric layer 102 and the metal region 103 represent a metallization layer, which may have substantially the same configuration as the metallization layer 113. Therefore, substantially the same processes as will be described below for forming the metallization layer 113 may also apply to the formation of the dielectric layer 102 and the metal region 103 including the barrier layer 104. Then, the dielectric barrier layer 105 may be deposited by plasma enhanced chemical vapor deposition (PECVD) on the basis of well-established process recipes to form a silicon nitride layer or a nitrogen-enriched silicon carbide layer. Thereafter, the dielectric layer 109 is deposited, for instance, by PECVD on the basis of TEOS and oxygen and/or ozone and a precursor material including fluorine.

Thereafter, the low-k dielectric layer 110 may be formed, for instance, by depositing SiCOH from trimethylsilane (3MS) or 4MS, and the like. After the deposition, a capping layer (not shown) may be deposited, for instance comprised of silicon dioxide, to provide a mechanically strengthened surface area of the low-k dielectric layer 110. Thereafter, an anti-reflective coating (ARC) layer may be deposited, for instance comprised of silicon oxynitride, to enhance the following photolithography, which is performed in accordance with well-established processes to provide a resist mask for patterning the layers 110 and 109 by anisotropic etch techniques, in which the trench 107 may be formed prior to the via 106 or in which the via 106 may be formed prior to the trench 107.

Thereafter, the conductive barrier layer 108 is formed above the structure and within the trench 107 and the via 106, wherein typically sputter techniques are employed to form the barrier layer 108 and also a seed layer (not shown) for a subsequent electrochemical deposition of metal, such as copper, within the via 106 and the trench 107. Frequently, copper is deposited by electroplating. After the metal deposition, any excess material of the metal, the barrier layer 108 and the seed layer are removed by, for instance, chemical mechanical polishing (CMP), during which the optional capping layer for strengthening the surface of the dielectric layer 110 may act as a layer for stopping the CMP process. Finally, the dielectric barrier layer 114 may be deposited, for instance in the form of silicon nitride or nitrogen-enriched silicon carbide by means of PECVD.

As is evident from the above description, a highly complex manufacturing process is required, wherein the electrical performance of the device 100 is less advanced compared to a device having a metallization layer 113 that is substantially fully formed of a low-k material. With the continuous shrinkage of feature sizes, which also requires the formation of densely spaced metal-filled trenches 107 and densely spaced vias 106, the moderately high permittivity of the metallization layer 113 due to the silicon dioxide in the via layer 111 may result in significant signal propagation delays. On the other hand, providing a low-k material in the via layer 111 in the above configuration may be a less desirable option owing to the reduced device reliability.

In view of the situation described above, there exists a need for an improved technique that avoids or at least reduces the effects of one or more of these problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of a metallization layer of reduced permittivity while at the same time providing superior resistance against electromigration compared to conventional metallization layers having a low-k material in the metal line layer and the via layer. The present invention is based on the concept that the behavior of a low-k dielectric layer stack may be significantly influenced by the provision of a dielectric layer creating compressive stress within the layer stack. That is, the reliability of the metallization layer comprising a low-k material in the metal line layer and the via layer may be enhanced by creating compressive stress within the via layer.

According to one illustrative embodiment of the present invention, a method comprises forming a metal region in a dielectric layer formed above a substrate and forming a dielectric barrier layer on the metal region. Moreover, the method further comprises forming a stress layer having an intrinsic compressive stress above the dielectric barrier layer and forming a low-k dielectric layer above the dielectric barrier layer.

According to another illustrative embodiment of the present invention, a semiconductor device comprises a substrate and a metal line layer formed above the substrate, wherein the metal line layer comprises a low-k dielectric material with a plurality of metal lines formed therein. The semiconductor device further comprises a dielectric barrier layer formed above the metal line layer and a dielectric stress layer formed above the dielectric barrier layer, wherein the dielectric stress layer has an intrinsic compressive stress. Additionally, the device comprises a via layer located above the dielectric stress layer, wherein the via layer comprises a metal-containing via formed in a dielectric material, the dielectric barrier layer and the dielectric stress layer.

### BRIEF DESCRIPTION OF THE DRAWINGS

The invention may be understood by reference to the following description taken in conjunction with the accompanying drawings, in which like reference numerals identify like elements, and in which:

FIG. 1 schematically shows a semiconductor device including a metallization layer on the basis of a low-k material in the metal line layer and a conventional dielectric material in the via layer in accordance with a typical conventional technique;

FIGS. 2a-2c schematically show cross-sectional views of a semiconductor device in accordance with illustrative embodiments of the present invention, wherein a compressive stress layer is formed at least in the via layer; and

FIG. 3 schematically shows a graph representing measurement results illustrating a comparison of the electrical performance of a conventionally fabricated device and a device in accordance with the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept that a low-k interconnect structure, i.e., a metallization layer, the dielectric material of which is substantially comprised of a low-k dielectric, may effectively be strengthened in that one or more material layers including compressive stress and exhibiting a higher mechanical stability or strength are introduced into the metallization layer. In particular embodiments of the present invention, the stress layer with intrinsic compressive stress is located in the vicinity of an interface formed between a metal line and a dielectric barrier material that is provided as a dielectric buffer material between the low-k dielectric material and the metal. With reference to the drawings, further illustrative embodiments of the present invention will now be described in more detail.

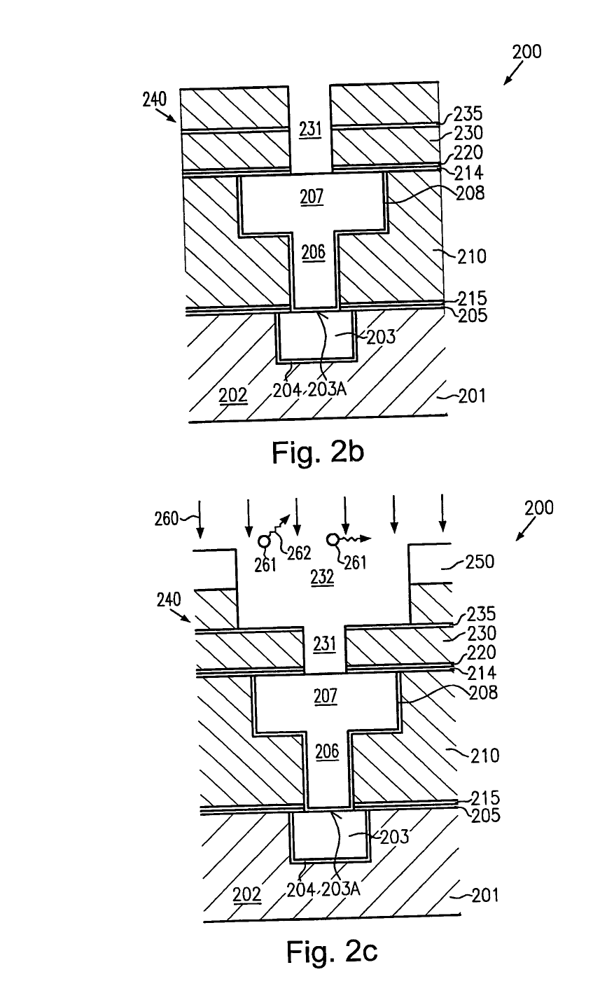

FIG. 2a schematically shows a cross-sectional view of a semiconductor device 200 which may represent any advanced device requiring a sophisticated interconnect structure or metallization layer including a low-k dielectric material. In this respect, it should be appreciated that the term “low-k dielectric material” refers to any dielectric material having a relative permittivity of approximately 3.1 and less. Moreover, the term “low-k metallization layer” should be understood to describe a metallization layer including a low-k dielectric material as the preponderant amount of material of the dielectric material in the metallization layer to reduce the signal propagation delay time compared to an equivalent metallization layer, which also includes a substantial portion of a “conventional” dielectric material such as silicon dioxide, fluorine-doped silicon dioxide and the like. Since the effect of signal propagation delay of metallization layers becomes significant for semiconductor devices of critical dimensions of approximately 0.18 μm and less, the present invention may be employed with devices having critical dimensions of 180 nm and significantly less and especially with devices of critical dimensions of 130 nm and less.

The semiconductor device 200 comprises a substrate 201 that is representative of any appropriate substrate having formed thereon or therein circuit elements such as transistors, capacitors, conductive lines, etc, which for convenience are not shown in FIG. 2a. A dielectric layer 202 is formed over the substrate 201 and includes a metal region 203, which may represent any of these circuit elements or portions thereof or wherein the metal region represents a metal line of a metallization layer. The metal region 203 may have formed on the side walls and a bottom surface a conductive barrier layer 204, which may be comprised of tantalum, tantalum nitride, titanium, titanium nitride, and the like. A first dielectric barrier layer or capping layer 205 is formed on the dielectric layer 202 and the metal region 203 and may be comprised of a diffusion blocking material such as silicon nitride or nitrogen-enriched silicon carbide, when the metal region 203 comprises copper. However, other materials may be used for the dielectric barrier layer 205, such as silicon dioxide and the like, if, for example, the metal region 203 represents a contact portion directly connecting to a circuit element. In some embodiments, the dielectric barrier layer 205 may have an intrinsic compressive stress in the range of approximately 200-500 MPa (Megapascal). In the following it is referred to embodiments in which the metal region 203 represents a copper-containing metal line. In these embodiments, it may be advantageous that the dielectric barrier layer 205 be provided to optimize the diffusion blocking effect without considering the stress characteristics of the layer 205. Therefore, in one particular embodiment, a dielectric stress layer 215 may be formed above the dielectric barrier layer 205, wherein the stress layer 215 comprises intrinsic compressive stress with a magnitude as specified before. In one particular embodiment, the stress layer 215 is formed on the barrier layer 205, whereas, in other embodiments, the stress layer 215 is located in an intermediate location within a low-k dielectric layer 210, which represents the low-k dielectric material of a low-k metallization layer 213 formed above the dielectric layer 202 and the metal region 203. In one illustrative embodiment, the dielectric layer 210 may be comprised of hydrogen-containing silicon oxycarbide (SiCOH), while in other embodiments other materials may be used, such as MSQ, HSQ, SILK, SiCOH and the like. A metal-containing trench 207 and a metal-containing via 206 may be formed in the dielectric layer 210 so that an upper portion of the metallization layer 213 may be considered as a metal line layer 212, while a lower portion thereof may represent a via layer 211. The metal in the trench 207 and the via 206 may be comprised of copper or a copper alloy and may be separated from the surrounding dielectric material by a conductive barrier layer 208, which may be comprised of one or more layers including materials such as are specified above with reference to the conductive barrier layer 204. The metallization layer 213 may further comprise a dielectric barrier layer or capping layer 214 followed by a further dielectric stress layer 220. The barrier layer 214 may be comprised of nitrogen-enriched silicon carbide (SiCN) to maintain the overall permittivity at a low level, whereas, for less critical applications, silicon nitride may be appropriate. Similar to the dielectric barrier layer 215, the barrier layer 220 may have an intrinsic compressive stress as specified above and may, in one particular embodiment, be comprised of silicon dioxide or fluorine-doped silicon dioxide that is formed from TEOS.

A typical process flow for forming the semiconductor device 200 as shown in FIG. 2a may comprise the following processes. After the formation of the metal region 203 and of any circuit elements in and on the substrate 201, the dielectric barrier layer 205 may be deposited by any appropriate well-known deposition technique, such as plasma enhanced chemical vapor deposition. Depending on the material composition, deposition parameters may be controlled to create a desired compressive stress, if compatible with process constraints, as will be described below in context with the layer 215. Thereafter, the dielectric stress layer 215 may be deposited by PECVD from TEOS when the layer is comprised of silicon dioxide. During the deposition, a certain amount of fluorine-containing precursors may be added to obtain fluorine-doped silicon dioxide having a reduced permittivity compared to silicon dioxide. During this deposition process, at least one process parameter is controlled to create the layer 215 with a specified amount of compressive stress. For instance, the amount of stress created during the deposition of the layer 215 may depend on the gas mixture, the deposition temperature, and the magnitude of the bias voltage created by, for instance, the low frequency bias power, which may usually be available in advanced CVD tools allowing a dual frequency operation.

For instance, with a Producer™ system from Applied Materials, Inc, a silicon dioxide layer having a compressive stress in the range of 300-400 MPa may be obtained on the basis of the following process parameters. The pressure during the deposition may be adjusted to approximately 3-6 Torr while the high frequency power for establishing a plasma ambient may be set to approximately 70-150 watts, resulting in an appropriate power density within the plasma atmosphere that is also determined by the specific geometric configuration of the reactor chamber. The power supplied in the form of low frequency energy is set to approximately 250-350 watts. The deposition temperature is selected to be approximately 350-450° C., for instance approximately 400° C., and the gas flow for the carrier gas helium is set to approximately 1000-4000 sccm (standard cubic centimeter per minute), for example, approximately 3000 sccm, while oxygen is supplied with a flow rate of approximately 1000-1400 sccm. TEOS is supplied with an amount of approximately 1800-2000 mg per minute. With the above specified deposition tool and the process parameters as specified before, a deposition rate of approximately 5-8 nm per second may be obtained and a non-uniformity rate across a 200 mm substrate of approximately 1-2% may be achieved. The index of refraction is approximately 1.46-1.50. A thickness of the silicon dioxide layer may range from approximately 10-100 nm or even more, depending on process and device requirements.

It is to be appreciated that other process parameters may be established on the basis of the above teaching, when different deposition tools and/or substrate diameters are used. In some embodiments, the dielectric barrier layer 205 may also be provided in the form of a layer including compressive stress, wherein the layer 205 may be formed in accordance with well established PECVD recipes, wherein one or more process parameters are adjusted to obtain the desired compressive stress. For instance, the ion bombardment during the deposition of silicon nitride may be adjusted to a low level by correspondingly reducing or switching off any low frequency bias power to thereby create compressive stress in the layer 205.

Thereafter, the low-k dielectric layer 210 may be formed, for instance, in one particular embodiment by depositing hydrogen-containing silicon oxycarbide from oxygen and trimethylsilane (3MS) in accordance with well-established process recipes. In other embodiments, SiCOH may be deposited from 4MS, OMCTS or any other appropriate precursors. In some embodiments, the stress layer 215 and the low-k dielectric layer 210 may be deposited by an in situ process, i.e., the layers 215 and 210 may be deposited within the same process chamber without breaking the vacuum while depositing the layer 215 and the layer 210. In one illustrative embodiment, the layer 215 may be positioned at any intermediate location within the low-k dielectric layer 210, which may be achieved by correspondingly changing the process parameters in the process chamber to intermittently deposit silicon dioxide with a specified intrinsic stress at a desired position. In one particular embodiment, the stress layer is formed on the layer 205. In still other embodiments, two or more layers 215, having for example a thickness of approximately 40-80 nm, may be deposited within the low-k dielectric material by correspondingly modifying the deposition process for the layer 210.

In yet further embodiments, after the deposition of the stress layer 215, the low-k dielectric layer 210 may be formed by means of spin-on techniques when viscous materials are used as low-k dielectric, such as MSQ, HSQ and the like. After the formation of the low-k dielectric layer 210, a via opening may be formed through the dielectric layer 210 and the stress layer 215 and the barrier layer 205 by advanced photolithography and anisotropic etch techniques. Thereafter, a further photolithography process may be carried out to provide a resist mask (not shown) for forming the trench 207 by a further anisotropic etch process. For convenience, the formation of any capping layers for strengthening the low-k dielectric layer 210 at its upper surface and the provision of any ARC layers, required for advanced photolithography techniques, are not shown. Thereafter, the conductive barrier layer 208 may be formed within the trench 207 and the via 206 followed by the deposition of a seed layer (not shown) that is used during a subsequent electrochemical fill process. After the completion of the fill process, which may be performed as an electroplating process for filling in copper or a copper alloy, any excess material may be removed, for instance by chemical mechanical polishing (CMP), thereby also planarizing the resulting surface. Thereafter, the dielectric barrier layer 214 is formed above the dielectric layer 210 and the metal-filled trench 207, followed by the deposition of the dielectric stress layer 220. Regarding the layers 214 and 220, the same criteria apply as previously explained with reference to the layers 205 and 215.

As previously explained, advanced integrated circuits typically require a plurality of metallization layers, such as the layer 213, to provide the large number of electrical connections in accordance with the complex circuit design. With reference to FIG. 2b, the formation of one further metallization layer is described and should be considered as being representative for the formation of any further metallization layers, wherein the number of metallization layers depends on the complexity of the integrated circuit under consideration. For instance, presently available microprocessors may have up to eight copper-based metallization layers including a low-k material.

FIG. 2b schematically shows the semiconductor device 200 further comprising a second metallization layer 240 including a low-k dielectric layer 230 with an intermediate dielectric layer 235, which may act as an etch stop layer, an etch indicator layer or, in one particular embodiment, may act as a stress layer which is provided at a position that is correlated with a depth of a trench still to be formed in an upper portion of the low-k dielectric layer 230. Moreover, a via 231 is formed through the layers 230, 235, 220 and 214.

The metallization layer 240 may be formed in accordance with processes as are previously described with reference to the metallization layer 213. For example, the low-k material for the layer 230 may be deposited from 3MS, 4MS and the like, if the layer 230 is substantially comprised of SiCOH. In other embodiments, spin-on techniques may be used to apply a polymer material in accordance with process requirements. After the low-k material for the layer 230 with a specific first thickness is deposited, the layer 235 may be deposited which may, in one particular embodiment, be accomplished by depositing a highly compressive silicon dioxide layer from TEOS. Thereafter, the formation of the layer 230 may be continued to obtain the finally desired thickness and composition of the layer 230. Again, the deposition of any capping layers for strengthening the surface of the low-k dielectric material is not shown. Moreover, as previously noted, the formation of any ARC layers required for the subsequent photolithography is not illustrated in FIG. 2b. It should also be appreciated that with regard to the formation of the layer 235 and the layer 230 the same criteria apply as previously explained with the layers 210 and 215. That is, in some embodiments, the formation of the layers 230 and 235 may be carried out as an in situ process, thereby significantly reducing the process complexity. Moreover, since the layer 235 may be used as an etch indicator layer, even if it is provided as a stress layer having intrinsic compressive stress, the location of the layer 235 within the layer 230 may be controlled to be correlated with a depth to be etched into the upper portion of the layer 230 for forming a trench according to a dual damascene technique.

For instance, the position of the layer 235 may substantially correspond to the bottom of the trench to be formed. In other embodiments, the layer 235 may represent an etch stop layer comprised of silicon nitride or nitrogen-enriched silicon carbide and the like to reliably stop the trench etch process. In some embodiments, the layer 235, when being provided as an etch stop layer, may also be formed to exhibit a specified intrinsic compressive stress. As previously explained, the deposition process during the plasma enhanced chemical vapor deposition may correspondingly be adjusted to obtain the specified compressive stress. Moreover, instead of the via 231, a corresponding trench may be formed first and thereafter the via 231 may be etched.

After the formation of the layer 230 and any ARC layers, a corresponding resist mask may be formed by photolithography, which is then used to form the via 231 by an anisotropic etch process wherein the process may reliably be stopped on and in the layer 214.

FIG. 2c schematically shows the semiconductor device 200 during an anisotropic etch process, indicated by 260, for forming a trench 232 in the low-k dielectric layer 230, that is, in an upper portion thereof. To this end, a resist mask 250 is formed above the low-k dielectric layer 230 wherein, again, for convenience, any additional capping layers and/or anti-reflective coatings formed within the low-k dielectric layer 230 are not shown. The resist mask 250 and possibly any additional capping layers and anti-reflecting layers are formed in accordance with well-established deposition and photolithography techniques. Thereafter, the anisotropic etch process 260 is performed wherein, at a final phase of the process, gaseous byproducts 261 may be liberated when the etch front reaches the dielectric layer 235, which has a different composition as it may be comprised of silicon dioxide or fluorine-doped silicon dioxide, silicon nitride and the like. In particular, excited cyanide (CN) molecules and excited carbon monoxide (CO) molecules may be generated when the etch front arrives at the layer 235, when comprised of silicon dioxide, thereby initiating the emission of corresponding light wavelengths 262 that may effectively be detected by a corresponding end point detection system (not shown) as is typically provided in readily available etch tools. Hence, by identifying prominent lines within the emitted light wavelengths 262, the etch process 260 may be stopped with high precision. Thus, although the etch selectivity may be moderately low between the layer 235, when provided in the form of a compressive silicon dioxide layer, and the low-k SiCOH, an increased reliability in etching the trench 232 may be achieved, while the compressive stress of the layer 235 still provides enhanced mechanical stability and thus improved electrical performance of the metallization layer 240. In other embodiments, if concerns in view of parasitic capacitance are less critical, the layer 235 may be provided in the form of an etch stop layer, thereby still further improving the reliability of the trench etch process 260. Thereafter, the process may be continued as is already described with reference to the metallization layer 213, thus corresponding conductive barrier layers may be deposited, and thereafter the trench 232 and the via 231 may be filled with a copper-based metal.

As a result, the present invention provides a technique that enables the formation of low-k metallization layers wherein the low-k material is also provided within the via level while still maintaining an enhanced electrical behavior due to the provision of the stress layers 205, 215 and/or 235. Hereby, for specific low-k materials, a reduced complexity of the deposition process may be obtained, in that the deposition of the stress layers 205, 215 and 235 may be carried out as an in situ process in combination with the deposition of the low-k material.

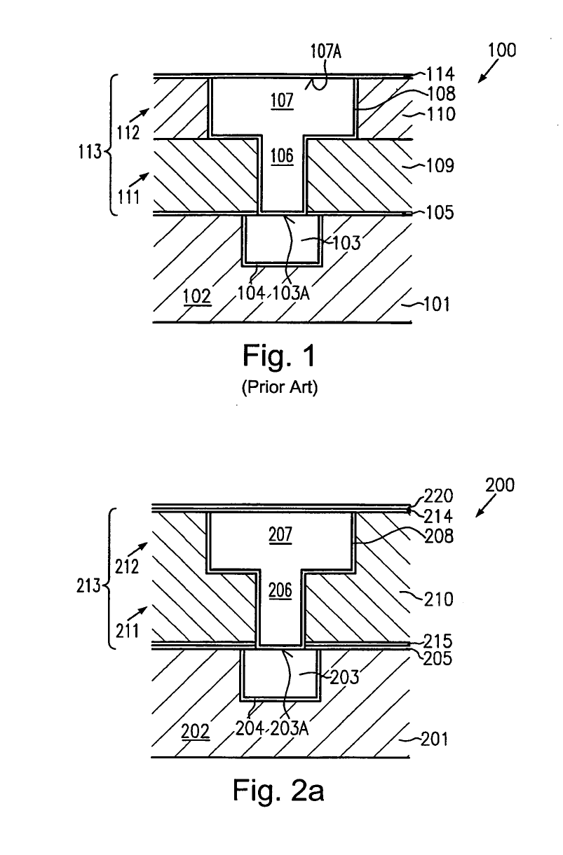

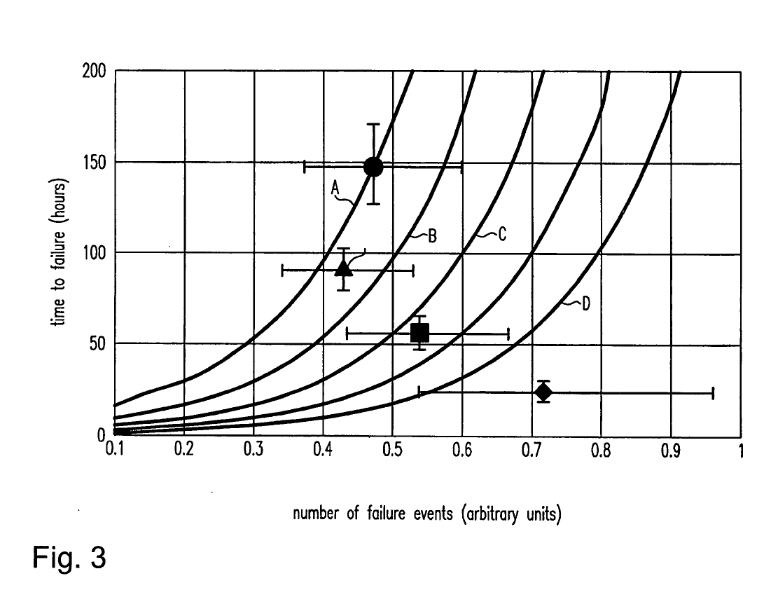

FIG. 3 schematically shows measurement results of an electromigration test for a semiconductor device having two metallization layers, such as layers 213 and 240, stacked on top of each other for a plurality of devices formed in accordance with the present invention and for a plurality of comparison devices. During the electromigration test, the devices were operated with current densities that are also encountered during the normal operation, while the temperature was significantly increased compared to normal operating conditions. In particular, the temperature was raised to approximately 325° C. to promote current-induced electromigration effects. In FIG. 3, curve A represents a calculated curve matching measurement results representing a semiconductor device formed in accordance with the present invention, wherein particularly a compressive silicon dioxide layer is formed on top of the respective dielectric barrier layer (e.g., the layers 215 and 220 in FIGS. 2b and 2c). Curve B in FIG. 3 represents a conventional device, i.e., comprising a hybrid metallization layer as is shown in FIG. 1. Moreover, curve C represents a device having a structure similar to the device represented by curve A, except for the fact that the corresponding layers 215 and 220 are provided without intrinsic compressive stress. Finally, curve D in FIG. 3 represents the semiconductor device of FIG. 1, wherein the entire metallization layer is substantially comprised of a low-k SiCOH. The horizontal axis represents the number of failure events in arbitrary units, while the vertical axis depicts the time to failure in hours. As is evident from FIG. 3, the number of failure events of the inventive semiconductor devices, represented by curve A, are substantially less for a given time to failure, or the time to failure is significantly higher for a given number of failure events during the electromigration tests. In particular, the comparison with curve D, representing the device having a full low-k dielectric layer, clearly shows the superior reliability, while the electrical behavior is substantially the same, as the total permittivity of the respective metallization layers is substantially the same.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a metal region in a dielectric layer formed above a substrate;
forming a dielectric barrier layer on said metal region;
forming a stress layer having an intrinsic compressive stress above said dielectric barrier layer; and
forming a low-k dielectric layer above said dielectric barrier layer.

2. The method of claim 1, further comprising patterning said low-k dielectric layer to form a trench and a via therein.

3. The method of claim 1, wherein said stress layer is deposited on said dielectric barrier layer.

4. The method of claim 1, further comprising forming at least one further stress layer having an intrinsic compressive stress at an intermediate position within said low-k dielectric layer.

5. The method of claim 1, wherein forming said stress layer and said low-k dielectric layer is accomplished by an in situ process.

6. The method of claim 1, wherein said intrinsic compressive stress is in the range of approximately 300-400 MPa.

7. The method of claim 1, further comprising forming at least one of an etch stop layer and an etch indicator layer at an intermediate position within said low-k dielectric layer.

8. The method of claim 7, wherein said at least one of an etch stop layer and etch indicator layer comprises an intrinsic compressive stress.

9. The method of claim 1, wherein said stress layer is comprised of silicon dioxide.

10. The method of claim 9, wherein said silicon dioxide layer is formed from TEOS.

11. The method of claim 1, wherein said low-k dielectric material comprises SiCOH.

12. A semiconductor device, comprising:
a substrate;
a metal line layer formed above said substrate, said metal line layer comprising a low-k dielectric material with a plurality of metal lines formed therein;
a dielectric barrier layer formed above said metal line layer;
a dielectric stress layer formed above said dielectric barrier layer, said dielectric stress layer having an intrinsic compressive stress; and
a via layer located above said dielectric stress layer, said via layer comprising a metal-containing via formed in a dielectric material, in said dielectric barrier layer and said dielectric stress layer.

13. The semiconductor device of claim 12, wherein said dielectric material is a low-k dielectric.

14. The semiconductor device of claim 13, wherein said low-k material of the metal line layer and the dielectric material of said via layer are comprised of substantially the same material.

15. The semiconductor device of claim 12, wherein said intrinsic compressive stress has a magnitude in the range of approximately 300-400 MPa.

16. The semiconductor device of claim 12, wherein said dielectric stress layer is formed on said dielectric barrier layer.

17. The semiconductor device of claim 12, further comprising a second dielectric stress layer formed at an intermediate position within at least one of said metal line layer and said via layer.

18. The semiconductor device of claim 17, wherein said second dielectric stress layer is located between said metal line layer and said via layer.

19. The semiconductor device of claim 12, wherein said dielectric stress layer is comprised of silicon dioxide.

20. The semiconductor device of claim 12, wherein said low-k dielectric material comprises SiCOH.

21. The semiconductor device of claim 12, further comprising at least one of an etch stop layer and an etch indicator layer between said metal line layer and said via layer.
